(19) United States
(12) Patent Application Publication
(10) Pub. No.: US 2015/0255559 A1
(43) Pub. Date: Sep. 10, 2015

(54) SEMICONDUCTOR DEVICE AND METHOD FOR MANUFACTURING THE SAME

(71) Applicant: Kabushiki Kaisha Toshiba, Tokyo (JP)

(72) Inventors: Takako Motai, Yokohama Kanagawa (JP); Mahadevaiah Gopal, Kawasaki Kanagawa (JP)

(21) Appl. No.: 14/476,401

(22) Filed: Sep. 3, 2014

(30) Foreign Application Priority Data
Mar. 10, 2014 (JP) 2014-046952

(51) Int. Cl. H01L 29/45; H01L 29/201; H01L 29/66; H01L 21/285; H01L 21/02; H01L 21/263; H01L 29/20; H01L 29/778

(52) U.S. Cl. CPC H01L 29/452; H01L 29/2003; H01L 29/201; H01L 29/7787; H01L 21/28575; H01L 21/02664; H01L 21/263; H01L 29/66462

(57) ABSTRACT

According to one embodiment, a semiconductor device includes a first semiconductor layer and a first electrode. The first semiconductor layer includes a nitride semiconductor including a first metal. The first electrode is provided in contact with the first semiconductor layer. The first electrode includes a first region, a second region and a third region. The first region includes a compound of the first metal and a second metal or an alloy of the first metal and the second metal. The second metal has reducing properties for the first semiconductor layer. The second region is provided between the first semiconductor layer and the first region and includes the first metal and the second metal. The third region is provided between the first semiconductor layer and the second region and includes a compound of the first metal and nitrogen.

### CROSS-REFERENCE TO RELATED APPLICATIONS

This application is based upon and claims the benefit of priority from the Japanese Patent Application No. 2014-046952, filed on Mar. 10, 2014; the entire contents of which are incorporated herein by reference.

### FIELD

Embodiments described herein relate generally to a semiconductor device and a method for manufacturing the same.

### BACKGROUND

For example, a compound semiconductor having a wide band gap is used as a material of a high breakdown voltage or high frequency power element. In a semiconductor device using a compound semiconductor, a semiconductor layer is not doped with impurities and there is a case where it is difficult to form a good contact between an electrode and the semiconductor. It is desired to stably form a good (e.g., ohmic) contact between an electrode and a semiconductor. A semiconductor device in which a contact with good electrical characteristics is formed is desired.

### BRIEF DESCRIPTION OF THE DRAWINGS

FIG. 1A and FIG. 1B are schematic section views illustrating a semiconductor device according to a first embodiment;

FIG. 2 is a graph illustrating characteristics of the semiconductor device according to the first embodiment;

FIG. 3 is a graph illustrating characteristics of the semiconductor device according to the first embodiment;

FIG. 4 is a graph illustrating characteristics of a semiconductor device in a reference example;

FIG. 5A to FIG. 5D are schematic diagrams illustrating a manufacturing process of the semiconductor device according to the first embodiment;

FIG. 6A to FIG. 6C are schematic diagrams illustrating the semiconductor device according to the embodiment;

FIG. 7 is a schematic section view illustrating part of a semiconductor device according to a second embodiment; and

FIG. 8 is a graph illustrating the characteristics of the semiconductor device.

### DETAILED DESCRIPTION

According to one embodiment, a semiconductor device includes a first semiconductor layer and a first electrode. The first semiconductor layer includes a nitride semiconductor. The nitride semiconductor includes a first metal. The first electrode is in contact with the first semiconductor layer. The first electrode includes a first region, a second region and a third region. The first region includes one of a first substance and a second substance. The first substance is a first compound of the first metal and a second metal. The second substance is an alloy of the first metal and the second metal. The second metal is configured to reduce the first semiconductor layer. The second region is provided between the first semiconductor layer and the first region. The second region includes the first metal and the second metal. The third region is provided between the first semiconductor layer and the second region. The third region includes a second compound of the first metal and nitrogen.

According to one embodiment, a semiconductor device includes a first electrode and a first semiconductor layer. The first electrode includes a first portion including a first metal, and a second portion including a compound of the first metal and nitrogen. The first semiconductor layer includes a nitride semiconductor. The nitride semiconductor includes the first metal. The second portion is provided between the first semiconductor layer and the first portion. A concentration of titanium in the first electrode is less than 5 atomic percent.

According to one embodiment, a method of manufacturing a semiconductor device is disclosed. The semiconductor device includes a first semiconductor layer and a first electrode in contact with the first semiconductor layer. The first semiconductor layer includes a nitride semiconductor. The nitride semiconductor includes a first metal. The first electrode includes a first region, a second region and a third region. The second region is provided between the first semiconductor layer and the first region. The third region is provided between the first semiconductor layer and the second region. The first region includes one of a first substance and a second substance. The first substance is a first compound of the first metal and a second metal. The second substance is an alloy of the first metal and the second metal. The second metal is configured to reduce the first semiconductor layer. The second region includes the first metal and the second metal. The third region includes a second compound of the first metal and nitrogen. The method includes forming the first electrode. The forming the first electrode includes forming a first metal layer on the first semiconductor layer, forming a second metal layer on the first metal layer, and forming a third metal layer on the second metal layer. The first metal layer includes the first metal and the second metal. The second metal layer includes the second metal. The third metal layer includes the first metal.

According to one embodiment, a method of manufacturing a semiconductor device is disclosed. The semiconductor device includes a first electrode and a first semiconductor layer. The first electrode includes a first portion including a first metal, and a second portion including a compound of the first metal and nitrogen. The first semiconductor layer includes a nitride semiconductor including the first metal. The method includes forming the first electrode. The forming the first electrode includes removing nitrogen of the first semiconductor layer by irradiating the first semiconductor layer with plasma of a gas containing hydrogen, and forming a metal layer on the first semiconductor layer. The metal layer includes the first metal.

Various embodiments will be described hereinafter with reference to the accompanying drawings.

The drawings are schematic or conceptual; and the relationships between the thicknesses and widths of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

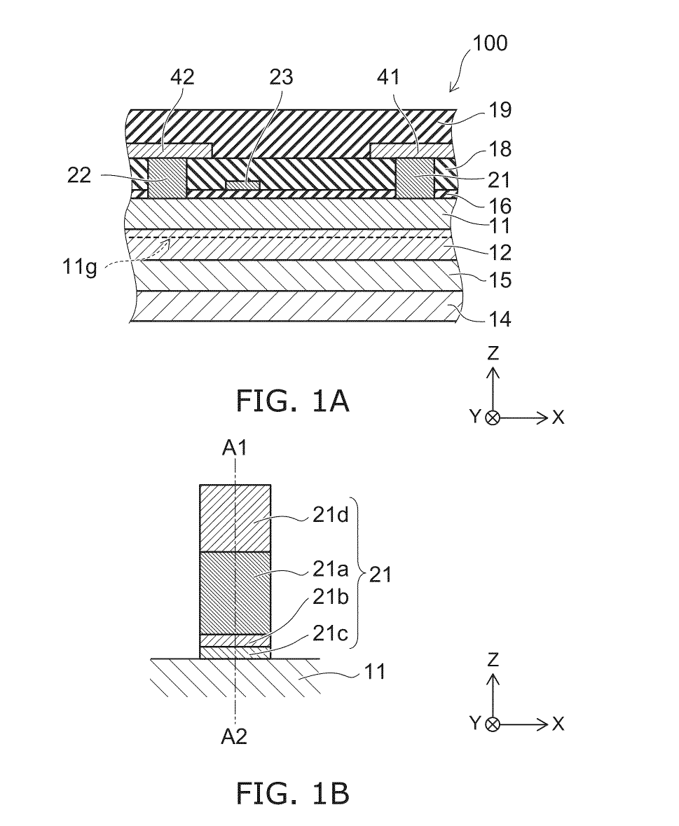

FIG. 1A and FIG. 1B are schematic section views illustrating a semiconductor device according to a first embodiment.

As shown in FIG. 1A, a semiconductor device 100 according to the embodiment includes a first electrode 21 (drain electrode) and a first semiconductor layer 11. In the example, the semiconductor device 100 further includes a second semiconductor layer 12, a substrate 14, a foundation layer 15, a gate insulating film 16, an insulating layer 18, an insulating layer 19, a second electrode 22 (source electrode), a gate electrode 23 (control electrode), a first wire 41, and a second wire 42. The semiconductor device 100 is, for example, an HEMT (High Electron Mobility Transistor).

In the example, the first electrode 21 is a drain electrode and the second electrode 22 is a source electrode. The first electrode 21 may be used as a source electrode in the transistor. The second electrode 22 may be used as a drain electrode in the transistor.

As the substrate 14, for example, a silicon substrate is used. The substrate 14 may be, for example, a SiC (silicon carbide) substrate or a sapphire substrate. The substrate 14 may be removed by backside grinding or laser liftoff after the element is formed.

The foundation layer 15 is provided on the substrate 14. The foundation layer 15 includes, for example, a nitride semiconductor. The foundation layer 15 includes, for example, AlₐGa₁₋ₐN (0≦a≦1). The foundation layer 15 includes, for example, a plurality of nitride semiconductor layers. The foundation layer 15 includes, for example, a plurality of AlN layers, a plurality of AlGaN layers, and a plurality of GaN layers. Each of these layers is stacked repeatedly in order of the AlN layer, the AlGaN layer, and the GaN layer, for example, in the direction in which the substrate 14 and the foundation layer 15 are stacked. The foundation layer 15 is, for example, a superlattice layer. The foundation layer 15 is not limited to this and may be a stacked film including a plurality of AlGaN layers in which the composition ratio of Al is changed stepwise between AlN and GaN. The foundation layer 15 may be, for example, one layer (so-called inclined layer) in which the composition ratio of Al is changed continuously from AlN toward GaN. The foundation layer 15 is provided in accordance with necessity and may be omitted.

The second semiconductor layer 12 is provided on the foundation layer 15. The second semiconductor layer 12 includes, for example, a nitride semiconductor. The first semiconductor layer 11 is provided on the second semiconductor layer 12. The first semiconductor layer 11 includes, for example, a nitride semiconductor including the first metal. The first metal is, for example, aluminum (Al).

The first semiconductor layer 11 includes, for example, Alₓ₁Ga₁₋ₓ₁N (0<x1<1). The second semiconductor layer 12 includes, for example, Alₓ₂Ga₁₋ₓ₂N (0≦x2<x1). The second semiconductor layer 12 is, for example, a GaN layer. The second semiconductor layer 12 is, for example, non-doped. The second semiconductor layer 12 includes, for example, no impurities. A composition ratio of Al of the first semiconductor layer 11 is, for example, higher than the composition ratio of Al of the second semiconductor layer 12. The first semiconductor layer 11 is, for example, an AlGaN layer. For example, the second semiconductor layer 12 may be formed into an AlGaN layer and the first semiconductor layer 11 may be formed into an AlGaN layer having an Al composition ratio higher than an Al composition ratio of the second semiconductor layer 12.

The second semiconductor layer 12 is, for example, a channel layer and the first semiconductor layer 11 is, for example, a barrier layer. The first semiconductor layer 11 and the second semiconductor layer 12 form a heterojunction. Further, the first semiconductor layer 11 may be configured by a plurality of layers and part of the first semiconductor layer 11 may be a p-type layer including impurities, such as Mg.

As described previously, the composition ratio of Al of the first semiconductor layer 11 is higher than the composition ratio of Al of the second semiconductor layer 12. In other words, a lattice constant of the first semiconductor layer 11 is smaller than a lattice constant of the second semiconductor layer 12. Consequently, distortion is generated in the first semiconductor layer 11 and piezo polarization is generated within the first semiconductor layer 11 due to the piezo effect. Consequently, a two-dimensional electron gas 11g is formed in the vicinity of an interface of the second semiconductor layer 12 with the first semiconductor layer 11.

The gate insulating film 16 is provided on the first semiconductor layer 11. In the gate insulating film 16, for example, SiO₂, SiN, Al₂O₃, TiO₂, Ta₂O₅, HfO₂, ZrO₂, or the like is used. The gate insulating film 16 is provided in accordance with necessity and may be omitted.

The first electrode 21 is provided on the first semiconductor layer 11. The first electrode 21 contacts, for example, the first semiconductor layer 11. The first electrode 21 ohmic-contacts, for example, the first semiconductor layer 11.

The second electrode 22 is provided on the first semiconductor layer 11. The second electrode 22 is disposed on the first semiconductor layer 11 separate from the first electrode 21. The second electrode 22 contacts, for example, the first semiconductor layer 11. The second electrode 22 ohmic-contacts, for example, the first semiconductor layer 11. To the second electrode 22, it is possible to apply the same configuration as the configuration of the first electrode 21, to be described later.

The gate electrode 23 is provided on the first semiconductor layer 11 between the first electrode 21 and the second electrode 22. The gate electrode 23 is disposed separate from each of the first electrode 21 and the second electrode 22. Further, in the example, the gate electrode 23 is provided on the gate insulating film 16. In the gate electrode 23, for example, nickel (Ni) and gold (Au) are used. For example, Au is stacked on Ni.

In the semiconductor device 100, by controlling a voltage applied to the gate electrode 23, the concentration of the two-dimensional electron gas 11g under the gate electrode 23 increases or decreases. Consequently, a current flowing between the first electrode 21 and the second electrode 22 is controlled.

The first wire 41 is provided, for example, on the first electrode 21. The first wire 41 is electrically connected with the first electrode 21. The first wire 41 is electrically connected with, for example, each of a plurality of the first electrodes 21. The second wire 42 is provided, for example, on the second electrode 22. The second wire 42 is electrically connected with the second electrode 22. The second wire 42 is electrically connected with, for example, each of a plurality of the second electrodes 22.

The insulating layer 18 and the insulating layer 19 are provided on the gate insulating film 16. Portions other than each of the electrodes 21 to 23 are filled with the insulating layer 18, for example, on the gate insulating film 16. The insulating layer 19 is provided, for example, on the insulating layer 18 and covers the first wire 41 and the second wire 42.

The direction from the first semiconductor layer 11 toward the first electrode 21 is taken to be a Z-axis direction. The direction vertical to the Z-axis direction is taken to be an X-axis direction. The direction vertical to the Z-axis direction and vertical to the X-axis direction is taken to be a Y-axis direction.

FIG. 1B is a schematic section view illustrating the first electrode of the semiconductor device 100 according to the embodiment. As shown in FIG. 1B, the first electrode 21 according to the embodiment includes a first region 21a, a second region 21b, a third region 21c, and a fourth region 21d.

The second region 21b is provided between the first region 21a and the first semiconductor layer 11. The third region 21c is provided between the first semiconductor layer 11 and the second region 21b.

The first region 21a is a region including the first metal and the second metal. For example, the first region 21a includes a compound (a first compound) or an alloy of the first metal and the second metal. As the first metal, for example, Al is used. As the second metal, for example, a reducing metal is used. The second metal has reducing properties, for example, for the first semiconductor layer 11. The second metal is configured to reduce the first semiconductor 11. As the second metal, for example, at least any one of titanium (Ti) and vanadium (V) is used. In the example, the first region 21a includes a compound or alloy of Al and Ti. For example, the first region 21a is a region including Ti₃Al.

The fourth region 21d is provided on the first region 21a. The fourth region 21d includes a metal different from the first metal and different also from the second metal. The fourth region 21d is provided in accordance with necessity. There is a case where the fourth region 21d includes a plurality of layers.

The second region 21b includes the first metal and the second metal. The third region 21c includes a compound (a second compound) of the first metal and nitrogen.

For example, the third region 21c contacts the first semiconductor layer 11. The third region 21c is, for example, an interface layer between the first semiconductor layer 11 and the first electrode 21. For example, the second region 21b contacts the third region 21c. For example, the second region 21b contacts the first region 21a.

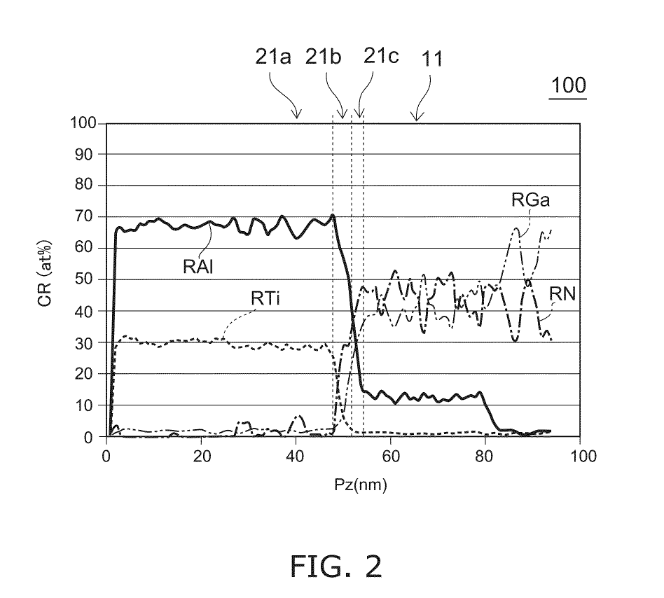

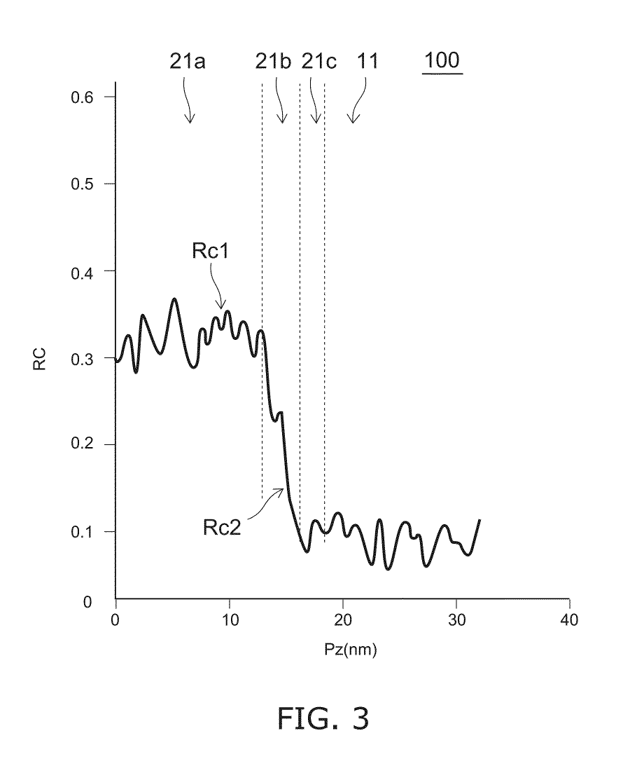

FIG. 2 and FIG. 3 are graphs illustrating characteristics of the semiconductor device according to the first embodiment. It is possible to obtain the graphs illustrated in FIG. 2 and FIG. 3 by, for example, the energy dispersive X-ray spectroscopy (EDX).

FIG. 2 illustrates a concentration CR (atomic percent) in the first electrode 21 and in the first semiconductor layer 11 of the semiconductor device 100.

FIG. 2 illustrates a concentration along an A1-A2 line in FIG. 1B. The vertical axis in FIG. 2 represents the concentration CR and the horizontal axis in FIG. 2 represents a distance Pz in units of nanometers (nm) from the position where measurement is started in the Z-axis direction. FIG. 2 illustrates a nitrogen concentration RN, a Ti concentration RTi, an Al concentration RAI, and a Ga concentration RGa. It is possible to obtain the concentration of an element by converting intensity measured by the EDX into a concentration.

FIG. 3 illustrates a ratio of the concentration of the second metal to the concentration of the first metal, i.e., a ratio of numbers of atoms in the first electrode 21 and in the first semiconductor layer 11 of the semiconductor device 100. FIG. 3 shows a change in concentration ratio along the A1-A2 line in FIG. 1B. In the example, the first metal is Al and the second metal is Ti.

The horizontal axis in FIG. 3 represents the distance Pz (nm) from the position where measurement is started in the Z-axis direction. The vertical axis in FIG. 3 represents the concentration ratio of the second metal to the first metal, i.e., a ratio of numbers of atoms. FIG. 3 shows a ratio of numbers of atoms within a fixed volume at a certain position in the Z-axis direction, i.e., a concentration ratio and shows a change in concentration ratio in the Z-axis direction.

The concentration ratio is obtained by a ratio between the concentration into which converted from the detected intensity of Al measured by the EDX by using a sensitivity coefficient and the concentration of Ti into which converted from the detected intensity of Ti in the same manner.

The position indicated by Pz=0 in each of FIG. 2 and FIG. 3 is not necessarily the same position in the specimen. The position indicated by Pz=0 in each of FIG. 2 and FIG. 3 corresponds to the position where measurement is started in the measurement by the EDX. Further, the range of the distance Pz in each of FIG. 2 and FIG. 3 depends on the range where measurement is performed.

As shown in FIG. 2 and FIG. 3, in the first region 21a, the first electrode 21 contains Ti. For example, the first region 21a includes a compound or an alloy of Al and Ti. In FIG. 3, the concentration ratio of the second metal to the first metal at a first position within the first region 21a is taken to be Rc1. The concentration ratio Rc1 is not less than 0.25 and not more than 0.5 and preferably, not less than 0.26 and not more than 0.4. For example, a concentration ratio Rc in the first region 21a is about 0.3. For example, the variation of the concentration ratio Rc in the first region 21a is within ±20% of the average of the concentration ratio Rc in the first region 21a.

The third region 21c (e.g., interface layer) contains nitrogen and Al. The third region 21c is, for example, a region including aluminum nitride (AlN). As shown in FIG. 2, in the third region 21c, the concentration RTi is low. For example, the third region 21c hardly contains titanium. For example, the concentration of the second metal (e.g., Ti) in the third region 21c is not more than 10 atomic percent (at %). As shown in FIG. 3, the concentration ratio Rc in the third region 21c is, for example, not more than 0.15 and preferably not more than 0.1. The length (thickness) along the Z-axis direction of the third region 21c is, for example, not less than 1 nm and not more than 2 nm. For example, the variation of the concentration ratio Rc in the third region 21c is within ±20% of the average of the concentration ratio Rc in the third region 21c.

As shown in FIG. 3, the second region 21b is a region in which the concentration ratio changes along the Z-axis direction between the first region 21a and the third region 21c. The concentration ratio of the second metal to the first metal at a second position within the second region 21b is taken to be Rc2. The concentration ratio Rc2 changes from about 0.33 to about 0.1 and indicates that a reduction of Ti in number with respect to Al is increasing.

The maximum value of a distribution along the Z-axis direction of the concentration ratio Rc1 in the first region 21a is larger than the maximum value of a distribution along the Z-axis direction of the concentration ratio Rc2 in the second region 21b. In other words, between the first region 21a and the third region 21c, the distribution along the Z-axis direction of the concentration ratio Rc does not have a peak larger than the maximum value of the concentration ratio Rc1 in the first region 21a.

The length (thickness) along the Z-axis direction of the second region 21b is, for example, not less than 1 nm and not more than 4 nm. For example, the thickness of the second region 21b is preferably not less than 2 nm and not more than 3 nm.

As described above, in the semiconductor device 100 according to the embodiment, between the third region 21c where the Ti concentration is low and the first region 21a where a compound or alloy of Al and Ti is formed, the Ti concentration changes abruptly along the Z-axis direction. For example, the concentration ratio Rc changes at a rate of about 0.07 to 0.13 per 1 nm along the Z-axis direction in the second region 21b.

The concentration ratio Rc2 in the second region 21b is smaller than the concentration ratio Rc1 in the first region 21a. The distribution along the Z-axis direction of the concentration ratio Rc does not have a peak larger than, for example, the maximum value of the concentration ratio Rc1 in the first region 21a and changes in an inclined manner.

An electrode in which the concentration ratio between the first metal and the second metal has such a distribution is formed. As will be described later, consequently, a good (e.g., ohmic) electrical contact is obtained between the first electrode 21 and the first semiconductor layer 11. Consequently, it is possible to reduce the electric resistance.

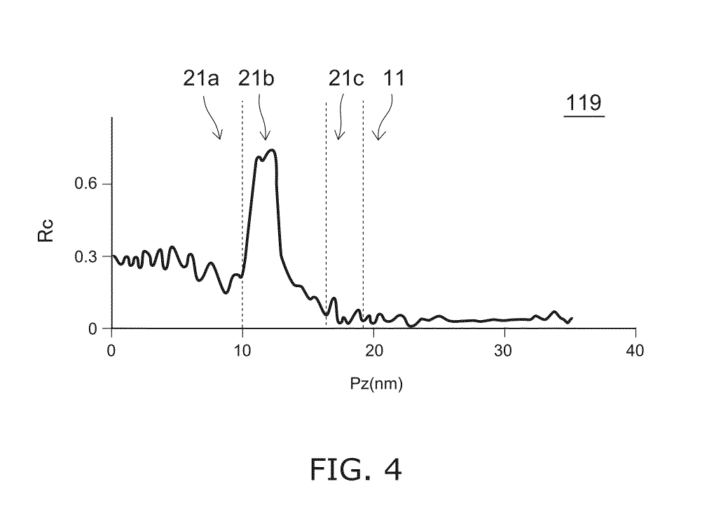

FIG. 4 is a graph illustrating characteristics of a semiconductor device in a reference example.

The horizontal axis in FIG. 4 represents the distance Pz (nm) from the measurement start position in the Z-axis direction. The vertical axis in FIG. 4 represents the concentration ratio Rc.

In a semiconductor device 119 illustrated in FIG. 4 also, the first electrode 21 and the first semiconductor layer 11 are provided. It is possible to apply the same configuration as the configuration described for the semiconductor device 100 to the first semiconductor layer 11 of the semiconductor device 119. In the semiconductor device 119 also, as the first metal, Al is used and as the second metal, Ti is used.

As shown in FIG. 4, in the first electrode 21 of the semiconductor device 119 in the reference example also, the first region 21a, the second region 21b, and the third region 21c are provided. The first region 21a of the semiconductor device 119 includes a compound or alloy of Al and Ti as the first region 21a of the semiconductor device 110 does. In the first region 21a of the semiconductor device 119 also, the concentration ratio Rc is, for example, not less than 0.2 and not more than 0.4. For example, the concentration ratio Rc is about 0.3.

The third region 21c of the semiconductor device 119 is an interface layer including a compound of Al and nitrogen like the first region 21c of the semiconductor device 100. In the semiconductor device 119 also, the third region 21c hardly contains, for example, Ti and the concentration ratio Rc is, for example, not more than 0.1.

On the other hand, the concentration ratio Rc in the second region 21b between the first region 21a and the third region 21c has a portion larger than the concentration ratio Rc in the first region 21a. For example, the concentration ratio Rc in the second region 21b has a portion where the concentration ratio Rc is not less than 0.6. For example, between the first region 21a and the interface layer, the distribution in the Z-direction of the concentration ratio Rc has a peak. This suggests that a compound or alloy of titanium and aluminum is not formed but a compound of Ti and other impurities is formed. According to the examination of the inventors of the application, in the case where, for example, such a compound of Ti is formed, the electric resistance at the interface between the electrode and the semiconductor layer is not ohmic. There is a case where it is difficult to stably obtain good electrical characteristics.

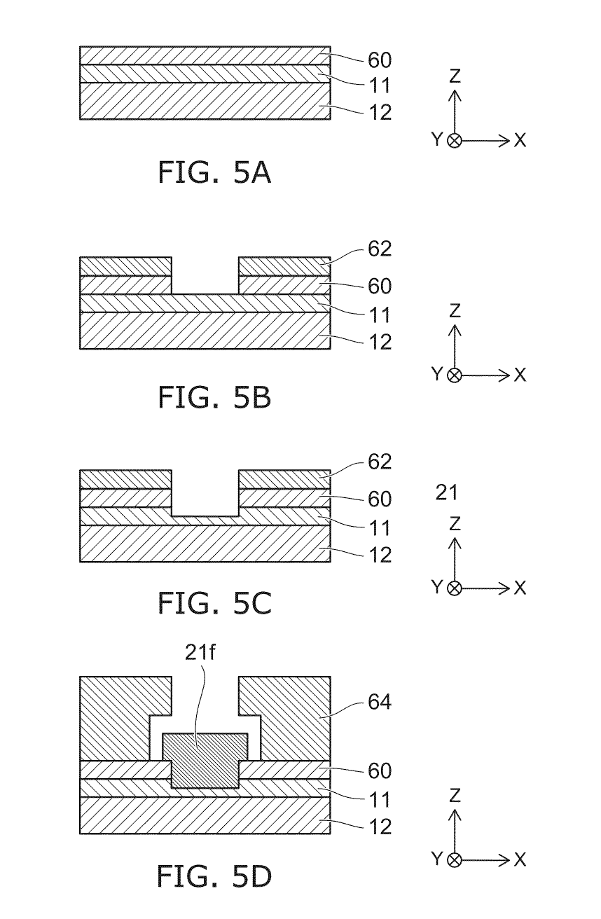

FIG. 5A to FIG. 5D are schematic diagrams illustrating a manufacturing process of the semiconductor device according to the first embodiment.

FIG. 5A to FIG. 5D illustrate processes to form the first electrode 21 in the manufacturing process of the semiconductor device 100. In FIG. 5A to FIG. 5D, part of components are omitted to make FIG. 5A to FIG. 5D easy-to-see.

As shown in FIG. 5A, on the substrate 14, the first semiconductor layer 11 and the second semiconductor layer 12 are formed. For example, on the first semiconductor layer 11, a passivation film 60 is formed. In the passivation film 60, for example, silicon nitride (SiN) is used. Formation of the passivation film 60 is performed in accordance with necessity and may be omitted as appropriate.

As shown in FIG. 5B, a pattern is formed in the passivation film 60. For example, on the passivation film 60, a resist 62 is formed and a pattern is formed in the resist by photolithography etc. By using the resist 62 as a mask, a pattern is formed in the passivation film 60 by using, for example, reactive ion etching etc. Consequently, part of the first semiconductor layer 11 is exposed.

As shown in FIG. 5C, for example, part of the first semiconductor layer 11 may further be etched. The etching of the first semiconductor layer 11 is performed, for example, in accordance with necessity and may be omitted as appropriate.

As shown in FIG. 5D, after removing the resist 62, a resist 64 is formed. For example, by vapor deposition, a metal layer 21f that forms the first electrode 21 is formed on the first semiconductor layer 11. Subsequently, the resist 64 is removed and heat treatment is performed. For example, heat treatment at temperatures not less than 500° C. and not more than 700° C. is performed. Consequently, the first electrode 21 is formed. For formation of the metal layer 21f, for example, the sputter method may be used.

In accordance with necessity, ions are implanted into the semiconductor layer 11 and the gate insulating film 16, the gate electrode 23, the insulating layer 18, etc., are formed. Consequently, the HEMT is completed.

The process to form the first electrode 21 (electrode forming process) shown in FIG. 5D is further described.

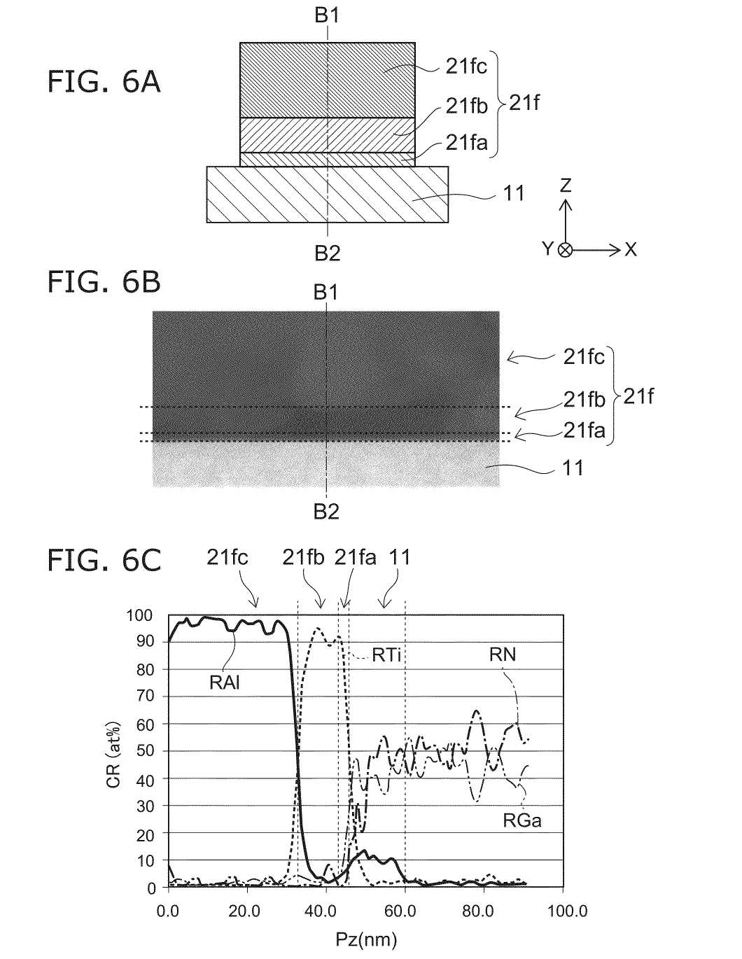

FIG. 6A to FIG. 6C are schematic diagrams illustrating the semiconductor device according to the embodiment.

FIG. 6A to FIG. 6C illustrate the metal layer 21f before heat treatment in the process to form the first electrode 21.

FIG. 6A illustrates a schematic section view in the process to form the first electrode 21. FIG. 6B is a photographic image corresponding to FIG. 6A.

As shown in FIG. 6A and FIG. 6B, in the process to form the first electrode 21, a first metal layer 21fa, a second metal layer 21fb, and a third metal layer 21fc are provided. The process to form the first electrode 21 includes a process to form the first metal layer 21fa, a process to form the second metal layer 21fb, and a process to form the third metal layer 21fc. On the third metal layer 21fc, a fourth metal layer 21fd (not shown) may be formed.

On the first semiconductor layer 11, for example, by vapor deposition, the first metal layer 21fa including the first metal and the second metal is formed. The concentration of the first metal in the first metal layer 21fa is, for example, not less than 10 at % and not more than 20 at %.

On the first metal layer 21fa, for example, by vapor deposition, the second metal layer 21fb is formed. The second metal layer 21fb includes the second metal.

On the second metal layer 21fb, for example, by vapor deposition, the third metal layer 21fc is formed. The third metal layer 21fc includes the first metal.

FIG. 6C illustrates a concentration along a B1-B2 line shown in FIG. 6A and FIG. 6B. The vertical axis in FIG. 6C represents the concentration CR (at %). The horizontal axis in FIG. 6C represents the distance Pz from the measurement start position in the Z-axis direction. In the example, as the first metal, Al is used and as the second metal, Ti is used. Further, in the first semiconductor layer 11, Alₓ₁Ga₁₋ₓ₁N (0<x1<1) is used. FIG. 6C illustrates the Al concentration RAI, the Ti concentration RTi, the Ga concentration RGa, and the nitrogen concentration RN. The concentration CR (at %) in FIG. 6C is, for example, the measurement result obtained by the EDX.

As shown in FIG. 6C, in the third metal layer 21fc, the Al concentration RAI is high. The third metal layer 21fc is, for example, an Al layer. The third metal layer 21fc hardly includes, for example, the second metal. The concentration of the second metal (e.g., Ti) in the third metal layer 21fc is, for example, not more than 5 at %.

In the second metal layer 21fb, the Ti concentration RTi is high. For example, the second metal layer 21fb is a Ti layer. The concentration of the first metal (e.g., Al) in the second metal layer 21fb is, for example, not more than 5 at %.

The first metal layer 21fa is, for example, a metal layer containing Al and Ti. The concentration of the first metal (e.g., Al) in the first metal layer 21fa is, for example, not less than 5 at % and not more than 20 at %. Preferably, the concentration in the first metal layer is not less than 10 at % and not more than 20 at %. A concentration of Al in the first metal layer 21fa is higher than a concentration of Al in the second metal layer 21fb.

In the first semiconductor layer 11, in correspondence to the concentration of Alₓ₁Ga₁₋ₓ₁N (0<x1<1), Al, Ga, and nitrogen are detected. As shown in FIG. 6C, it can be seen that the first semiconductor layer 11 contains Ga, Al, and nitrogen. For example, the Ga concentration RGa is not less than 50 at % and not more than 80 at %. The nitrogen concentration RN is, for example, not less than 10 at % and not more than 30 at %. For example, a concentration of Al in the first metal layer 21fa is lower than a concentration of Al in the first semiconductor layer 11.

The process to form the first electrode 21 includes a process to heat the first metal layer 21fa, the second metal layer 21fb, the third metal layer 21fc, and the first semiconductor layer 11 thus formed. For example, heating is performed at temperatures not less than 500° C. and not more than 700° C. Consequently, the first electrode having such a composition as described in FIG. 2 and FIG. 3 is formed. For example, an ohmic contact is formed. The electric resistance can be reduced.

The power element using a compound semiconductor with a wide band gap can have, for example, a high breakdown voltage and characteristics compatible with high frequencies. However, different from a semiconductor using silicon, in such a semiconductor with a wide band gap, it is difficult to form an ohmic contact just by forming an ohmic electrode on the semiconductor surface. Because of this, for example, heat treatment etc. is performed. For example, in the HEMT element using a stacked film of AlₓGa₁₋ₓN and GaN, the semiconductor layer is not doped. There is a case where it is difficult to stably form an ohmic contact.

On the other hand, in the embodiment, for example, like the first metal layer 21fa, the metal layer that contacts the AlGaN layer (first semiconductor layer) contains Al in a concentration of about 10% to 20%. It has been found out that a contact between the electrode and the semiconductor (e.g., ohmic contact) can be formed stably by forming a metal layer containing Ti and Al and having an Al concentration of about 10 to 20 at % and by heating the metal layer at temperatures in a predetermined range.

On the surface of the AlGaN layer, a layer including a reducing metal, such as Ti and V, like the first metal layer 21fa is formed. Then, heat treatment is performed at not less than 500° C. Consequently, the reducing metal, for example, such as Ti and V, removes nitrogen from the surface of the AlGaN layer and forms holes of nitrogen on the surface of the AlGaN layer. This forms, for example, an n-type layer.

Further, by performing heat treatment, for example, Al contained in the third metal layer 21fc diffuses to the AlGaN surface and reacts with nitrogen at the interface between the Ti layer and the AlGaN layer. Consequently, for example, the third region 21c including AlN is formed.

By heat treatment, for example, the second metal (e.g., Ti) included in the second metal layer 21fb and the first metal (e.g., Al) included in the third metal layer 21fc react and the first region 21a including a compound or alloy of the first metal and the second metal is formed. Between the first region 21a and the third region 21c, the second region 21b in which the concentration (concentration ratio Rc) changes is formed.

For example, the AlN layer (third region 21c) thus formed serves as, for example, an interface layer between the n-type layer formed on the AlGaN layer surface and the ohmic metal (first region 21a). Through the AlN layer, for example, a tunnel current flows. Consequently, for example, an ohmic contact can be formed.

In the embodiment, the first metal layer 21fa includes the reducing second metal, and thereby, it is possible to form, for example, an n-type layer. Further, the first metal layer 21fa includes the first metal. Consequently, in the above-mentioned heat treatment, the first metal in the first metal layer 21fa and nitrogen on the AlGaN layer surface easily react with each other. The interface layer is easy to stably form. Consequently, it is possible to stably obtain, for example, an ohmic contact.

For example, in the manufacturing process illustrated in FIG. 5A to FIG. 5D, there is a case where the surface of the first semiconductor layer 11 is contaminated by oxides or organic matter. There is a case where the second metal (Ti, V, or the like) deposited on the first semiconductor layer 11 forms a compound with these contaminants. Consequently, there is a case where, for example, in heat treatment, diffusion of Al contained in the third metal layer 21fc to the AlGaN layer is blocked. Further, by the reaction between the second metal and contaminants, there is a case where it is not possible to sufficiently remove nitrogen from the surface of the AlGaN layer. There is a case where it is not possible to form a sufficient n-type layer on the surface of the AlGaN layer.

For example, in the semiconductor device 119 in the reference example illustrated in FIG. 4, it can be considered that a compound of Ti and contaminants etc. is formed in the second region 21b between the first region 21a and the third region 21c. In the electrode having the concentration ratio Rc as illustrated in FIG. 4, for example, an n-type layer is not formed sufficiently and a good contact is not formed.

In contrast to this, in the embodiment, the first metal layer 21fa includes the first metal. Consequently, for example, formation of a compound of the second metal and contaminants etc. is suppressed. Further, even if a compound of the second metal and contaminants etc. is formed and diffusion of the first metal included in the third metal layer 21fc is blocked, a compound of the first metal and nitrogen is easily formed because the first metal layer 21fa includes the first metal. Consequently, it is possible to stably form a contact.

For example, the amount of nitrogen to be removed in the first semiconductor layer 11 depends on the thickness of the second metal layer deposited on the first semiconductor layer. The degree of easiness in which nitrogen on the surface of the first semiconductor layer 11 escapes depends on the composition of the first semiconductor layer 11 (e.g., Al composition on the AlGaN layer surface). The degree of easiness in which nitrogen on the surface of the first semiconductor layer 11 escapes depends on the state of the surface of the first semiconductor layer 11.

However, the composition of the surface of the first semiconductor layer 11 easily changes due to etching processing of the surface using F, Cl, or the like, plasma processing by hydrogen etc., high-temperature processing, etc. For example, there is a case where the composition of the surface of the AlGaN layer and the composition controlled in the epitaxial growth of the AlGaN layer are significantly different due to the processing in the manufacturing process. If the state of the surface changes as described above, there is a case where nitrogen is removed excessively more than supposed with a set thickness of the second metal layer. Consequently, for example, a compound (e.g., TiN) of the second metal is formed. For example, there is a case where diffusion of Al to the AlGaN layer is blocked and a good interface layer is difficult to form. For example, in the semiconductor device 119 in the reference example, diffusion of Al is blocked by TiN and a good interface layer is not formed. For example, an ohmic contact is not obtained.

In contrast to this, in the embodiment, the first metal layer 21fa includes the first metal. Consequently, for example, it is possible to prevent the second metal from removing nitrogen excessively from the surface of the first semiconductor layer 11. It is possible to suppress formation of a compound (e.g., TiN) of the second metal.

In the embodiment, on the first metal layer 21fa, for example, a layer of Ti not containing Al (second metal layer 21fb) is formed. By heat treatment, Al diffuses from the third metal layer 21fc. The reducing metal (second metal) removes nitrogen from the AlGaN layer surface and an n-type low resistance layer is formed.

In the first electrode 21 thus formed of the semiconductor device 100 according to the embodiment, for example, the concentration ratio Rc changes abruptly between the third region 21c (interface layer) and the first region 21a.

For example, the first metal layer 21fa includes the first metal, and thereby, an interface layer (third region 21c) including a compound of the first metal and nitrogen becomes easier to form on the surface of the first semiconductor layer 11. Consequently, for example, the concentration of the first metal becomes low in the vicinity of the boundary between the second region 21b and the third region 21c.

The first metal layer 21fa includes the first metal, and thereby, for example, a compound of the second metal and contaminants etc. on the AlGaN layer surface is difficult to form. Consequently, for example, diffusion of heat of the first metal is not blocked and the region (first region 21a) including a compound or alloy of the first metal and the second metal is easy to form. The distribution along the Z-axis direction of the concentration ratio Rc does not have a peak by the compound of the second metal and contaminants.

As described above, in the embodiment, the first region 21a and the third region 21c are easy to form. For example, the width of the second region 21b between the first region 21a and the third region 21c becomes narrow. The concentration ratio Rc in the second region 21b changes abruptly. According to the examination of the inventors of the application, it has been found out that the electrode thus formed and having the concentration (concentration ratio Rc) as illustrated in FIG. 3 has good electrical characteristics. For example, it is possible to obtain an ohmic contact.

### Second Embodiment

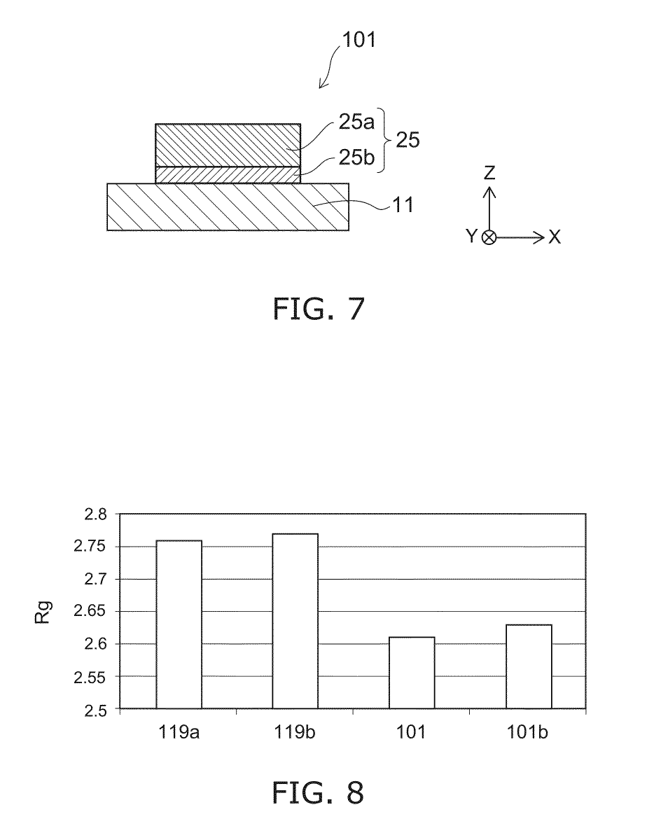

FIG.7 is a schematic section view illustrating part of a semiconductor device according to a second embodiment.

FIG. 7 illustrates a schematic section view of the first electrode 21 and the first semiconductor layer 11 in a semiconductor device 101. In the semiconductor device 101 also, the first semiconductor layer 11, the second semiconductor layer 12, the second electrode 22, the gate electrode 23, etc., are provided. It is possible to apply the same configuration as the configuration described for the semiconductor device 100 to these components.

A first electrode 25 in the semiconductor device 101 includes a first portion 25a and a second portion 25b. The first portion 25a includes the first metal. The second portion 25b includes a compound of the first metal and nitrogen.

For example, the first portion 25a is an Al layer. The second portion 25b is, for example, an interface layer of the first metal and the first semiconductor layer. The second portion 25b includes, for example, AlN.

In the first electrode 25, the concentration of the second metal (e.g., titanium) is low. For example, the first electrode 25 does not substantially include the second metal. The concentration of the second metal in the first electrode 25 is, for example, less than 5 atomic percent. Preferably, the concentration is less than 1 atomic percent.

An electrode forming process to form the first electrode 25 in the semiconductor device 101 is described.

A workpiece is prepared, in which the first semiconductor layer 11 is formed on a substrate and which is patterned by providing a resist, a passivation film, etc., in accordance with necessity as in the first embodiment.

The electrode forming process includes a process to remove nitrogen (e.g., of the surface) of the first semiconductor layer 11, a process to form a metal layer including the first metal, and a heat treatment process.

The top of the first semiconductor layer 11 is irradiated with plasma of a gas containing hydrogen. Consequently, (part of) nitrogen of the first semiconductor layer 11 is removed. Then, for example, on the surface of the first semiconductor layer 11, a low resistance n-type layer is formed. In the plasma processing, for example, a workpiece and a gas containing hydrogen are introduced into a chamber. The gas is turned into plasma by applying a high-frequency voltage. As the gas containing hydrogen, for example, a gas including NH₃ is used.

After performing plasma processing, on the first semiconductor layer, a metal layer including the first metal is formed. As the first metal, for example, Al is used. The metal layer does not contain, for example, Ti or V.

After forming the metal layer, heat treatment at temperatures, for example, not less than 500° C. and not more than 700° C. is performed. For example, the temperature is preferably not less than 600° C. In this manner, the first electrode 25 is formed.

FIG. 8 is a graph illustrating the characteristics of the semiconductor device.

FIG. 8 illustrates the characteristics of a semiconductor device 119a in a reference example, a semiconductor device 119b in a reference example, a semiconductor device 101a according to an embodiment, and a semiconductor device 101b according to an embodiment.

The vertical axis in FIG. 8 represents a concentration ratio Rg of a concentration of nitrogen to a concentration of Ga on the surface of the first semiconductor layer 11. In other words, Rg=(concentration of N)/(concentration of Ga). In the example, in the first semiconductor layer 11, AlGaN is used.

In the semiconductor device 119a, the surface of the first semiconductor layer 11 is not subjected to the plasma processing. In the semiconductor device 119b, the surface of the first semiconductor layer 11 is subjected to the plasma processing by using a gas not containing hydrogen (e.g., gas containing N₂). In the semiconductor device 101a and the semiconductor device 101b, the first semiconductor layer 11 is subjected to the same plasma processing as the plasma processing described for the semiconductor device 101. In the semiconductor device 101a, a flow rate of the gas including NH₃ is 30 cc/min. In the semiconductor device 101b, a flow rate of the gas including NH₃ is 100 cc/min.

As shown in FIG. 8, the concentration ratio Rg in the semiconductor device 119b in which the plasma processing is performed by using the gas not containing hydrogen is about the same as the concentration ratio Rg in the semiconductor device 119a in which the plasma processing is not performed. For example, Rg is about 2.75.

On the other hand, the concentration ratio Rg in the semiconductor device 101a is about 2.6 to 2.65. The concentration ratio Rg in the semiconductor device 101b is about 2.6 to 2.65. As described above, by using the gas containing hydrogen, the plasma processing is performed. Consequently, it is possible to remove nitrogen from the surface of the first semiconductor layer 11. On the surface of the first semiconductor layer 11, it is possible to form, for example, a low resistance n-type layer. In the semiconductor device 101 also, a contact having good electrical characteristics (e.g., ohmic contact) is formed.

According to the embodiments, it is possible to provide a semiconductor device the electrical characteristics of which are good and a method for manufacturing the same.

In the specification of the application, “perpendicular” refers to not only strictly perpendicular but also includes, for example, the fluctuation due to manufacturing processes, etc. It is sufficient to be substantially perpendicular.

Hereinabove, exemplary embodiments of the invention are described with reference to specific examples. However, the invention is not limited to these specific examples. For example, one skilled in the art may similarly practice the invention by appropriately selecting specific configurations of components such as the first semiconductor layer, the first electrode, the first metal, the second metal, the control electrode, the first to third regions, the first and second portions, and the first to third metal layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and methods for manufacturing the same practicable by an appropriate design modification by one skilled in the art based on the semiconductor devices and methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor layer including a nitride semiconductor, the nitride semiconductor including a first metal; and
a first electrode in contact with the first semiconductor layer, the first electrode including
a first region including one of a first substance and a second substance, the first substance being a first compound of the first metal and a second metal, the second substance being an alloy of the first metal and the second metal, the second metal being configured to reduce the first semiconductor layer,
a second region provided between the first semiconductor layer and the first region, the second region including the first metal and the second metal, and
a third region provided between the first semiconductor layer and the second region, the third region including a second compound of the first metal and nitrogen.

2. The device according to claim 1, wherein the first semiconductor layer and the first electrode form an ohmic contact.

3. The device according to claim 1, wherein the first metal includes aluminum.

4. The device according to claim 1, wherein a first ratio is lower than a second ratio, the first ratio is a ratio of a first concentration of the second metal in the second region to a second concentration of the first metal in the second region, the second ratio is a ratio of a third concentration of the second metal in the first region to a fourth concentration of the first metal in the first region.

5. The device according to claim 1, wherein the second metal includes at least one of titanium and vanadium.

6. The device according to claim 1, wherein a length of the second region along a first direction from the first semiconductor layer toward the first electrode is not less than 2 nanometers and not more than 3 nanometers.

7. The device according to claim 1, wherein a first ratio is higher than a second ratio, the first ratio is a ratio of a first concentration of the second metal in the first region to a second concentration of the first metal in the first region, the second ratio is a ratio of a third concentration of the second metal in the second region to a fourth concentration of the first metal in the second region.

8. The device according to claim 1, wherein a ratio of a first concentration of the second metal in the first region to a second concentration of the first metal in the first region is not less than 0.25 and not more than 0.5.

9. The device according to claim 1, wherein a concentration of the second metal in the third region is not more than 10 atomic percent.

10. A semiconductor device comprising:
a first electrode including
a first portion including a first metal, and
a second portion including a compound of the first metal and nitrogen; and
a first semiconductor layer including a nitride semiconductor, the nitride semiconductor including the first metal,
the second portion being provided between the first semiconductor layer and the first portion,
a concentration of titanium in the first electrode being less than 5 atomic percent.

11. The device according to claim 10, wherein the first metal includes aluminum.

12. The device according to claim 1, further comprising:
a second electrode provided at the first semiconductor layer;
a control electrode provided at the first semiconductor layer; and
a second semiconductor layer, the first semiconductor layer being provided at the second semiconductor layer.

13. The device according to claim 12, wherein the second semiconductor layer forms a hetero-junction with the first semiconductor layer.

14. The device according to claim 12, wherein
the first semiconductor layer includes Alₓ₁Ga₁₋ₓ₁N (0<x1<1), and
the second semiconductor layer includes Alₓ₂Ga₁₋ₓ₂N (0≦x2<x1).

15. A method of manufacturing a semiconductor device, the semiconductor device including a first semiconductor layer and a first electrode in contact with the first semiconductor layer, the first semiconductor layer including a nitride semiconductor, the nitride semiconductor including a first metal, the first electrode including a first region, a second region and a third region, the second region being provided between the first semiconductor layer and the first region, the third region being provided between the first semiconductor layer and the second region, the first region including one of a first substance and a second substance, the first substance being a first compound of the first metal and a second metal, the second substance being an alloy of the first metal and the second metal, the second metal being configured to reduce the first semiconductor layer, the second region including the first metal and the second metal, the third region including a second compound of the first metal and nitrogen, the method comprising
forming the first electrode, the forming the first electrode including
forming a first metal layer on the first semiconductor layer, the first metal layer including the first metal and the second metal,
forming a second metal layer on the first metal layer, the second metal layer including the second metal, and
forming a third metal layer on the second metal layer, the third metal layer including the first metal.

16. The method according to claim 15, wherein the forming the first electrode further includes heating the first metal layer, the second metal layer and the third metal layer at temperatures not less than 500° C.

17. The method according to claim 15, wherein a concentration of the first metal in the first metal layer is not less than 5 atomic percent and not more than 20 atomic percent.

18. The method according to claim 15, wherein a concentration of the first metal in the second metal layer is not more than 5 atomic percent.

19. The method according to claim 15, wherein the second metal includes one of titanium and vanadium.

20. A method of manufacturing a semiconductor device, the semiconductor device including a first electrode and a first semiconductor layer, the first electrode including a first portion including a first metal and a second portion, the second portion including a compound of the first metal and nitrogen, the first semiconductor layer including a nitride semiconductor including the first metal, the method comprising
forming the first electrode, the forming the first electrode including
removing nitrogen of the first semiconductor layer by irradiating the first semiconductor layer with plasma of a gas containing hydrogen, and
forming a metal layer on the first semiconductor layer, the metal layer including the first metal.

21. The method according to claim 15, wherein the first metal included aluminum.

22. The method according to claim 15, wherein the first semiconductor layer includes Alₓ₁Ga₁₋ₓ₁N (0<x1<1).
